(19) United States
(12) Patent Application Publication
(10) Pub. No.: US 2004/0115923 A1
(43) Pub. Date: Jun. 17, 2004

(54) Method of filling a via or recess in a semiconductor substrate

(76) Inventor: John Macneil, Cardiff (GB)

Correspondence Address: Volentine Francos, Suite 150, 12200 Sunrise Valley Drive, Reston, VA, 20191, US

(21) Appl. No.: 10/471,995

(22) PCT Filed: Apr. 22, 2002
(86) PCT No.: PCT/GB02/01847

(30) Foreign Application Priority Data
Apr. 26, 2001 (GB) 0110241.7

(51) Int. Cl. H01L 21/4763; H01L 21/44

(52) U.S. Cl. 438/622; 438/647; 438/672

(57) ABSTRACT

This invention relates to a method of filling a via or recess in a semiconductor substrate including: (i) depositing or forming a sacrificial layer on a functional dielectric layer, (ii) etching a via or recess through the sacrificial and functional layers; (iii) depositing metal onto the substrate by: (iv) lifting off or ablating the metal deposited on the surface of the sacrificial layers; (v) repeating steps (iii) and (iv) until the vias or recesses are at least full of metal; and (vi) removing any remaining sacrificial layer and any excess metal.

One of the problems that has arisen as manufacturer's have sought to replace aluminium with copper in semiconductor devices in order to reduce line resistance is that it is difficult to anisotropically etch copper. Unlike aluminium, copper does not form readily volatile chlorides and therefore cannot be plasma etched, except at higher temperatures. These higher temperatures give rise to problems, which are of sufficient practical significance to render plasma etching of copper unacceptable in connection with semiconductor devices. The general approach has therefore been to adopt damascene processing and, as presently developed, such processing requires chemical mechanical polishing (CMP) and its associated cleaning processes. Whilst CMP is a simple concept, akin to glass lens polishing, in practice it has many difficulties.

A further problem with damascene processing is that it requires the complete filling of trenches and vias with the conductive metal. However, line widths are shrinking, while insulating layer thicknesses remain broadly the same, with the result that the aspect ratio of the vias and recesses are becoming extremely high. For reasons well known in the art, the process of sputtering is problematic in connection with such features due to “necking”, which is the build up of material at the opening of the recesses or vias, blocking off the recess itself. This arises because most sputtering processes are not anisotropic. Whilst this problem can be overcome with materials having relatively low melting points, there are significant problems with copper due to its much higher melting point requiring elevated temperatures for long periods reducing such processes to academic interest only. Various approaches have been tried to overcome this difficulty, including the use of thermal pulses, e.g. from lasers, but none are in widespread commercial use. Attempts to get extremely pure copper to flow at relatively low temperatures are theoretically feasible, but it has proved to be an extremely slow process and again is not commercially viable. The industrial standard has therefore become copper plating. This like, CMP, is an extremely simple concept that in practice presents many difficulties. In addition barrier layers and a continuous metal film need to be present for the copper electroplating process to work. This often means that to complete the process both sputtering and electroplating apparatus are required. Further both CMP and plating present liquid effluent disposal problems.

From one aspect the invention consists in a method of filling a via or recess in a semiconductor substrate including:

(i) depositing or forming a sacrificial layer (that may be the photoresist used to pattern the dielectric layer) on a functional dielectric layer;

(ii) etching a via or recess through the sacrificial and functional layers;

(iii) if required, suitable dielectric, metal diffusion barrier layer(s) between the dielectric layer and the conductive metals may be deposited by any suitable means e.g. C.V.D or P.V.D.

(iv) depositing metal(s) onto the substrate e.g. by means of long-throw, or ionised physical vapour deposition or any suitable process;

(v) lifting off or ablating the metal deposited on the surface of the sacrificial layers;

(vi) repeating steps (iv) and (v) until the vias or recesses are at least full of metal; and

(vii) removing any remaining sacrificial layer and any excess metal.

It is preferred that the method of depositing the conducting metal(s) should be essentially anisotropic. For example a long throw sputter apparatus could be used and additionally or alternatively ionised and/or collimated physical vapour deposition could be used. Indeed any collimated deposition process would be suitable.

In a preferred embodiment the edges of the sacrificial layer which form part of the via or recess are profiled to reduce the metal deposited thereon. For example the edges may be at least partially undercut, e.g. by chamfering the edges by forming a groove or furrow therein. Such profiling may be configured to create, at least for the first deposition, a discontinuity between the metal in the recess or via and the metal on the sacrificial layer.

The sacrificial layer may be a low dielectric constant dielectric film, the photoresist used to pattern the dielectric layer and additionally or alternatively may be contiguous with the functional dielectric layer.

The barrier layer of (iii) may be removed from the sacrificial layer before deposition of the metal of (iv).

Step (v) may be performed by dry means, for example it may be performed by using CO₂ jet or super critical CO₂.

Step (v) may be performed by momentum transfer, stress fracturing or thermal stress. Additionally or alternatively solvents may be used.

Step (vii) may be performed by chemical mechanical polishing. However, because the metal has been lifted off the field of the substrate each time step (v) is performed, only relatively little metal has to be removed using this process.

Although the invention has been defined above, it is to be understood it includes any inventive combination of the features set out above or in the following description.

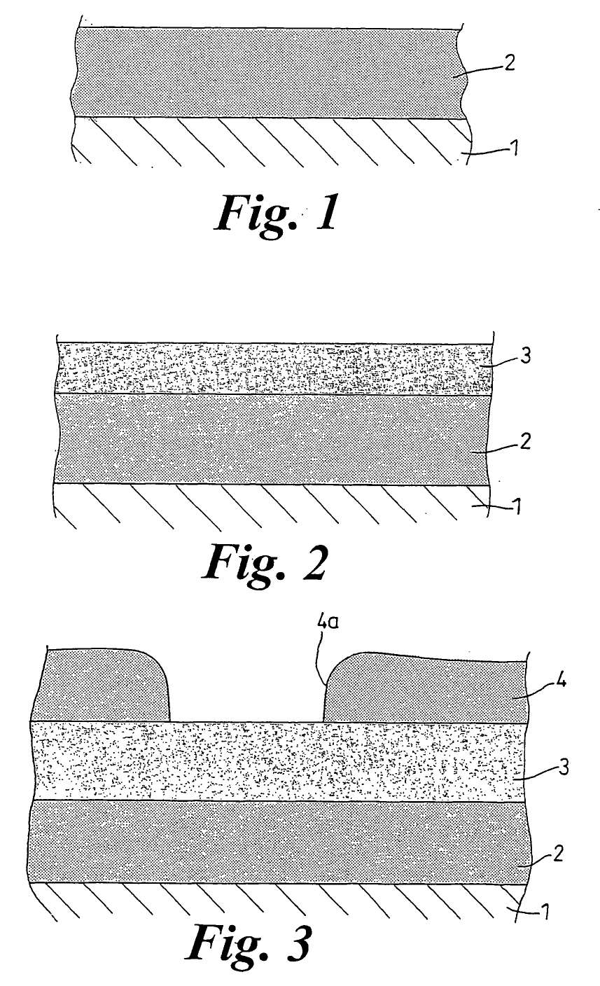

The invention can be performed in various ways and specific embodiments will now be described, by way of example, with reference to the accompanying drawings in which FIGS. 1 to 10 schematically illustrate a succession of steps of a method of forming and filling a via in a semiconductor substrate.

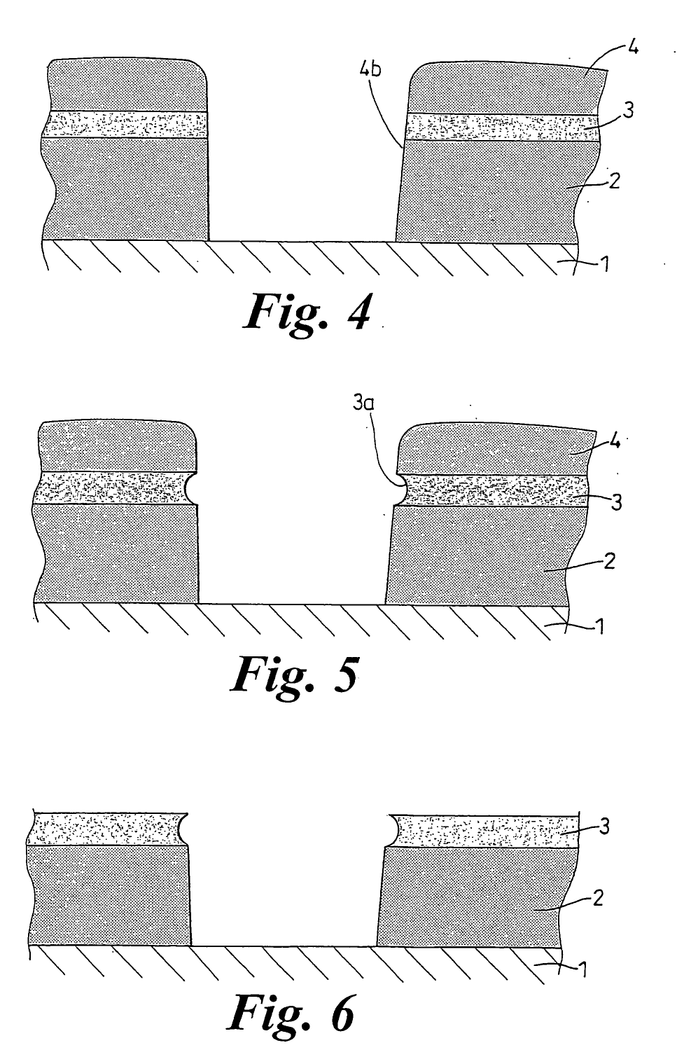

FIG. 1 is a scrap vertical section through a substrate where layer 1 is a metal layer of the substrate as has been formed previously. It may be the base silicon layer but is probably the upper layer of a structure formed on the base silicon layer. On to 1 has been deposited a functional dielectric layer 2. Other processes as are well known may be carried out e.g. metal pre-clean, barrier deposition, buried etch stop, hard mask and any process as necessary and in suitable sequence with the other processes, without altering the generality of this invention. Then, as can be seen in FIG. 2, a sacrificial dielectric layer 3 is formed on the functional dielectric layer 2 and that can be patterned with the photoresist 4 (see FIG. 3) in the conventional manner. The photoresist 4 defines an opening 4a through which a via 4b can be etched as shown at FIG. 4. The via 4b extends down to the upper surface of the layer 1.

The sacrificial layer 3 may then be notched using an isotropic selective etch, which is designed to etch the material of the layer 3, but not the other layers, so as to form the groove or furrow 3a indicated in FIG. 5.

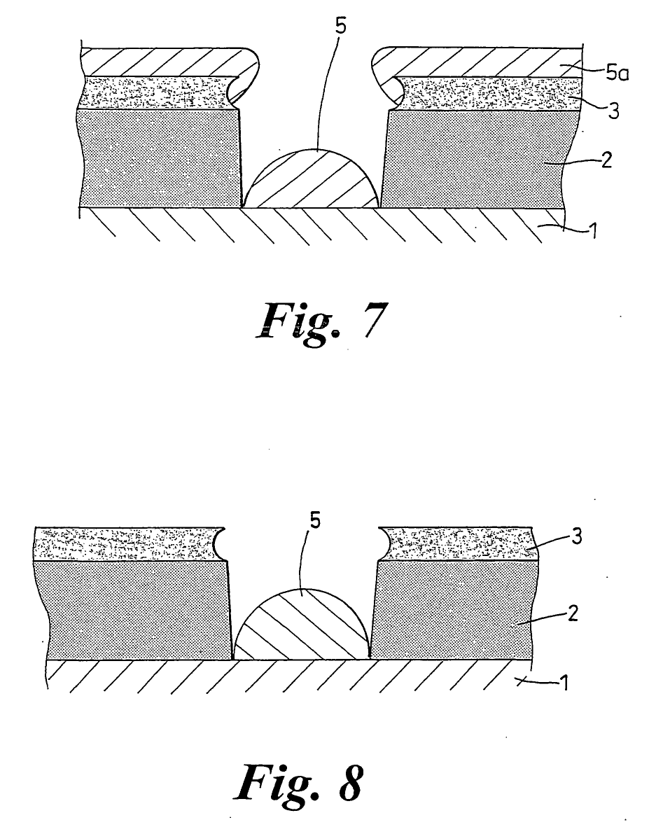

As can be seen in FIG. 6 the resist 4 is then removed. Metal, e.g. copper, is deposited by sputtering. Some of the sputtered metal reaches the bottom of the via 4a to form a deposit 5, whilst much else falls as field metal 5a. However, it will be noted that a discontinuity is created between the field metal 5a and the via metal 5 due to the groove or furrow 3a. This makes it possible to ablate the field metal 5a from the substrate to arrive at the position shown in FIG. 8. By repeating the process until the via metal 5 has at least filled the via 4a the via 4a can be filled without there being a significant d up of field metal 5a.

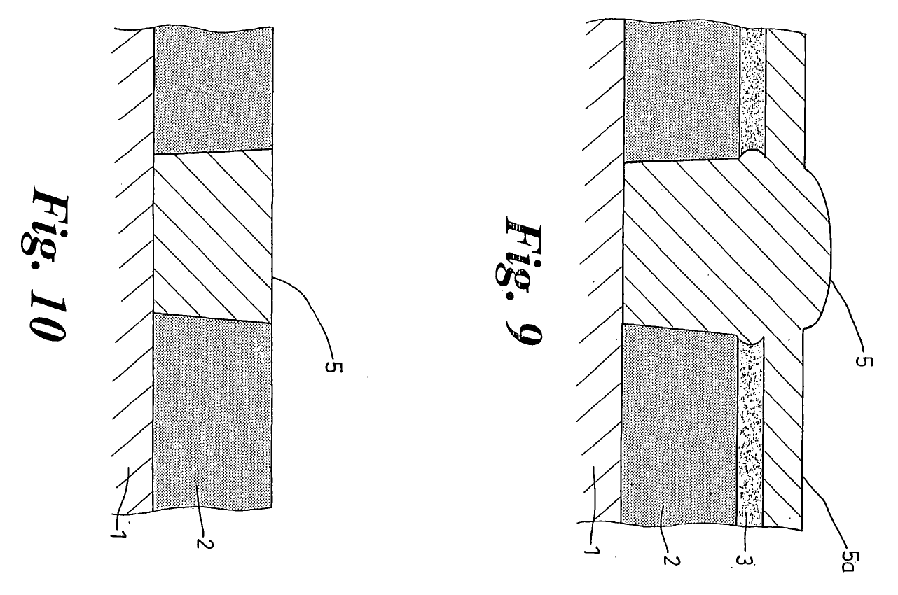

At this point it should be understood that the repeating of the process may well degrade the sacrificial layer 3 to some extent and the groove or notch 3a may become less well defined, but the provision of the sacrificial layer, whether grooved or not will tend to cause thinning of the metal between the field metal 5a and the via metal 5 enabling effective ablation of the field metal 5a until the metal 5 reaches fully up to the level of the sacrificial layer 3. The final deposition step may therefore need to be somewhat longer if, as is normally desirable, the deposition continues until the situation illustrated in FIG. 9 is reached, where the via 4a is more than filled. This approach should overcome any lack of uniformity in the sputtering process and make sure that all vias 4a are filled.

Once the FIG. 9 situation is reached, deposition can be stopped and the field metal 5a and sacrificial layer 3 removed by chemical mechanical polishing or any other suitable method to leave a filled via as illustrated in FIG. 10. By the use of a suitable thickness of sacrificial layer and relative height of groove it may be possible to obtain complete filling of the via and discontinuity with the field metal allowing ablation of the field metal and little or no CMP.

The step of ablation is preferably a dry one e.g. the use of CO₂ jets or suitable critical CO₂. Alternatively wet chemicals can be used. The means utilised for removal may include momentum transfer, oblation, stress fracturing, thermal stress or the dissolution of the immediate under-layer under the metal in the field area.

The sacrificial layer may be a low dielectric film that is compatible with the substrate and its processing. It may be deposited as a separate layer or may be contiguous with the upper layer of the functional dielectric.

It is preferred that the method be performed in a single apparatus under the control of the same stored computer programme. It would however equally be possible to perform the invention in separate sputter and etch chambers and an inspection chamber could be included to determine the level of filling of the via 4a.

It should be understood that the use of hard masks for the dielectric layers, barrier layers, etch step layers etc. may be used and their use is well known and understood. They do not alter the generality of the use of the selective removal of metal from the field by the use of a sacrificial underlayer, metal being preferentially left in recesses in the field of the surface of a substrate having electrical functionality.

1. A method of filling a via or recesses in a semiconductor substrate including:
(i) depositing or forming a sacrificial layer on a functional dielectric layer;
(ii) etching a via or recess through the sacrificial and functional layers;
(iii) depositing metal onto the substrate by:
(iv) lifting off or ablating the metal deposited on the surface of the sacrificial layers;
(v) repeating steps (iii) and (iv) until the vias or recesses are at least full of metal; and
(vi) removing any remaining sacrificial layer and any excess metal.

2. A method as claimed in claim 1 where a barrier layer is deposited and then removed other than in vias or recesses prior to the deposition of conductive metal layer(s).

3. A method as claimed in claim 1 or claim 2 wherein the edges of the sacrificial layer which form part of the via a recess are profiled to reduce-the metal deposited thereon.

4. A method as claimed in claim 3 wherein the edges are at least partially undercut.

5. A method as claimed in claim 3 or claim 4 wherein the edges are chamfered.

6. A method as claimed in claim 5 wherein the chamfer is in the form of a groove or furrow.

7. A method as claimed in any one of claims 3 to 6 wherein the profile is such as to create, at least for the first deposition, a discontinuity between the metal in the recess or via and the metal on the sacrificial layer.

8. A method as claimed in any one of the preceding claims wherein the sacrificial layer is a low dielectric constant dielectric film.

9. A method as claimed in any one of the preceding claims wherein the sacrificial layer is contiguous with the functional dielectric layer.

10. A method as claimed in any one of the preceding claims wherein step (iv) is performed by dry means.

11. A method as claimed in claim 10 wherein step (iv) is performed using a CO₂ jet or super critical CO₂.

12. A method as claimed in claim 10 wherein step (iv) is performed by momentum transfer, stress fracturing or thermal stress.

13. A method as claimed in any one of claims 1 to 8 wherein the performance of step (vi) includes the use of solvents.

14. A method as claimed in any one of the preceding claims wherein step (vi) is performed by chemical mechanical polishing.
